(19) United States
(12) Patent Application Publication
(10) Pub. No.: US 2022/0328722 A1
(43) Pub. Date: Oct. 13, 2022

(54) NITRIDE-BASED LIGHT EMITTING DIODE

(71) Applicant: XIAMEN SAN'AN OPTOELECTRONICS CO., LTD., XIAMEN (CN)

(72) Inventors: CHUNKAI TSENG, XIAMEN (CN); BING-YANG CHEN, XIAMEN (CN); JIANSHENG QIU, XIAMEN (CN)

(21) Appl. No.: 17/648,975

(22) Filed: Jan. 26, 2022

(30) Foreign Application Priority Data
Apr. 8, 2021 (CN) 202110376664.8

(51) Int. Cl. H01L 33/32; H01L 33/14; H01L 33/04

(52) U.S. Cl. CPC H01L 33/32; H01L 33/145; H01L 33/04

(57) ABSTRACT

A nitride-based light emitting diode (LED) includes a substrate, and an epitaxial structure. The epitaxial structure includes an n-type nitride-based semiconductor layer, a light emitting element, a first electron blocking layer, a p-type carbon-containing modulation layer and a p-type nitride-based semiconductor layer that are sequentially disposed on the substrate in such order. An amount of carbon present in the p-type carbon-containing modulation layer is higher than an amount of carbon present in each of the light emitting element and the first electron blocking layer.

### CROSS-REFERENCE TO RELATED APPLICATION

This application claims priority of Chinese Invention Patent Application No. 202110376664.8, filed on Apr. 8, 2021.

### FIELD

The disclosure relates to a semiconductor device, and more particularly to a nitride-based light emitting diode.

### BACKGROUND

Gallium nitride (GaN)-based light emitting diode (LED) is known for high light emitting efficiency, and has been widely used as a light source in various applications such as backlights, lightings, car lights, decorations, and electronic devices. The light emitting efficiency of the GaN-based LED mainly depends on two factors: (1) electron-hole radiative recombination efficiency in an active layer of the LED, i.e., internal quantum efficiency, and (2) light extraction efficiency. The internal quantum efficiency might be improved using several methods, for instance, band-gap design of quantum wells, improvement in crystal quality, enhancement in p-type hole injection efficiency, and suppression of electron overflow.

Band-gap design of quantum wells is a limiting factor for a GaN-based LED because only electron-hole recombination that happens in the active layer is considered as an effective recombination. In order to increase the internal quantum efficiency, it is critical to efficiently reduce electron overflow without adversely affecting p-type hole injection. Conventionally, an election blocking layer such as an aluminum gallium nitride (AlGaN) layer is formed to raise energy barrier so as to reduce electron overflow. However, the election blocking layer might adversely affect the p-type hole injection efficiency, and induce a two-dimensional electron gas (2DEG) at an interface region between the GaN layer and AlGaN layer where ineffective electron-hole recombination occurs, thereby causing reduction of light emitting efficiency of the LED.

### SUMMARY

Therefore, an object of the disclosure is to provide a nitride-based light emitting diode (LED) that can alleviate at least one of the drawbacks of the prior art.

According to the disclosure, the nitride-based LED includes a substrate, and an epitaxial structure. The epitaxial structure includes an n-type nitride-based semiconductor layer, a light emitting element, a first electron blocking layer, a p-type carbon-containing modulation layer and a p-type nitride-based semiconductor layer that are sequentially disposed on the substrate in such order. An amount of carbon present in the p-type carbon-containing modulation layer is higher than an amount of carbon present in each of the light emitting element and the first electron blocking layer.

### BRIEF DESCRIPTION OF THE DRAWINGS

Other features and advantages of the disclosure will become apparent in the following detailed description of the embodiment with reference to the accompanying drawings, of which:

FIG. 1 is a schematic view illustrating an embodiment of a nitride-based light emitting diode (LED) according to the disclosure;

FIG. 2 is a schematic view illustrating an active layer and an electron blocking layer of the embodiment of the nitride-based LED according to the disclosure;

FIG. 3 is a schematic energy diagram of a conventional LED; and

FIG. 4 is a schematic energy diagram of the embodiment of the nitride-based LED according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

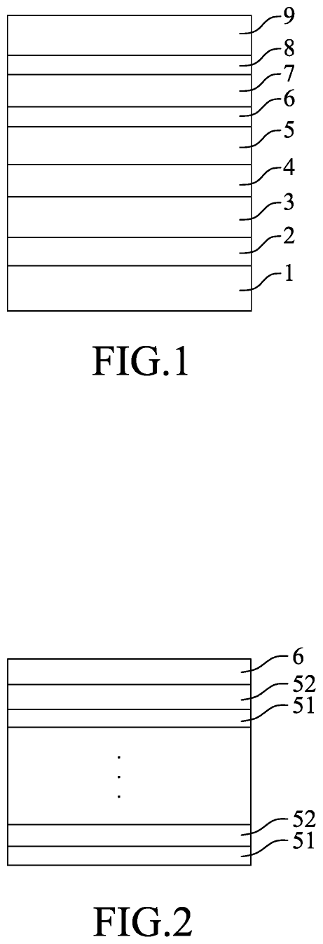

Referring to FIG. 1, an embodiment of a nitride-based light emitting diode (LED) according to the disclosure includes a substrate 1, and an epitaxial structure.

The substrate 1 may be made of a conducting material or an insulating material. For instance, the substrate 1 may be made of sapphire, aluminum nitride, gallium nitride, silicon, silicon carbide, gallium arsenide, or a single crystal oxide having a lattice constant similar to that of a nitride-based semiconductor material, but is not limited thereto. In certain embodiments, the substrate 1 may be patterned to form a plurality of microstructures on a surface thereof, so as to increase light emitting efficiency of the nitride-based LED.

The epitaxial structure includes an n-type nitride-based semiconductor layer 3, a light emitting element 5, a first electron blocking layer 6, a p-type carbon-containing modulation layer 7 and a p-type nitride-based semiconductor layer 9 that are sequentially disposed on the substrate 1 in such order.

The n-type nitride-based semiconductor layer 3 is doped with an n-type dopant, and thus serves as an electron donor for radiative recombination. Examples of the n-type dopant may include, but are not limited to, silicon (Si), germanium (Ge), tin (Sn), selenium (Se) and tellurium (Te). In this embodiment, the n-type nitride-based semiconductor layer 3 is doped with Si. The n-type nitride-based semiconductor layer 3 may have a doping concentration ranging from 1×10¹⁷ atoms/cm³ to 5×10¹⁹ atoms/cm³. The n-type nitride-based semiconductor layer 3 may have a thickness ranging from 1 μm to 4 μm. The n-type nitride-based semiconductor layer 3 may be formed as a single-layer structure or a multi-layered structure (such as a superlattice structure).

The light emitting element 5 serves as a region for radiative recombination of electrons and holes. The light emitting element 5 may be made of a predetermined semiconductor material, and composition of the semiconductor material may be adjusted according to a desired wavelength of light to be emitted. The light emitting element 5 may have a single-quantum well structure, or a multiple-quantum well (MQW) structure. That is, the light emitting element 5 includes at least one pair of layers, and each pair includes a well layer 51 and a barrier layer 52 that has a band gap larger than that of the well layer 51. Referring to FIG. 2, in this embodiment, the light emitting element 5 includes multiple pairs (such as 5 to 15 pairs) of layers, and the well layers 51 and the barrier layers 52 are alternately stacked. Each of the well layers 51 may be made of InGaN, and may have a thickness ranging from 2 nm to 4 nm. Each of the barrier layers 52 may be made of GaN, and may have a thickness ranging from nm to 15 nm. In other embodiments, the barrier layer 52 may be made of AlGaN, i.e., by doping GaN with trace amount of aluminum.

The first electron blocking layer 6 is configured to prevent electron overflow from the light emitting element 5. The first electron blocking layer 6 may be made of a material represented by a chemical formula of Al_{c}In_{d}Ga_{1-c-d}N, wherein c>0, d≥0 and c+d≤1.

For instance, the first electron blocking layer 6 may be made of AlN, AlGaN, AlInGaN, or combinations thereof. In certain embodiments, the first electron blocking layer 6 has a band gap greater than that of the barrier layer 52 of the light emitting element 5. In other embodiments, the band gap of the first electron blocking layer 6 is greater than that of gallium nitride. In yet other embodiments, an amount of aluminum present in the first electron blocking layer 6 is greater than that present in the barrier layer 52 of the light emitting element 5. The first electron blocking layer 6 may have a thickness not less than 1 nm so as to enhance reduction of electron overflow. If the first electron blocking layer 6 is too thick, the p-type hole injection efficiency may be adversely affected. Therefore, in certain embodiments, the thickness of the first electron blocking layer 6 may be not greater than 50 nm.

The p-type nitride-based semiconductor layer 9 is doped with a p-type dopant, and provides holes for recombination with electrons from the n-type nitride-based semiconductor layer 3. Examples of the p-type dopant may include, but are not limited to, magnesium (Mg), zinc (Zn), calcium (Ca), strontium (Sr) and barium (Ba). In this embodiment, the p-type nitride-based semiconductor layer 9 is doped with Mg. The p-type nitride-based semiconductor layer 9 may further include a p-type ohmic contact region (not shown in figures) that is heavily doped with a p-type dopant in an amount of, for instance, greater than 1×10²⁰ atoms/cm³, so as to form ohmic contact with a p-type electrode of the nitride-based LED.

The p-type carbon-containing modulation layer 7 is disposed between the first electron blocking layer 6 and the p-type nitride-based semiconductor layer 9. An amount of carbon present in the p-type carbon-containing modulation layer 7 is higher than an amount of carbon present in each of the light emitting element 5 and the first electron blocking layer 6. In certain embodiments, the amount of carbon present in the first electron blocking layer 6 is higher than that present in the light emitting element 5. The amount of carbon present in the p-type carbon-containing modulation layer 7 may range from 5×10¹⁶ atoms/cm³ to 1×10¹⁸ atoms/cm³. In this embodiment, the amount of carbon present in the p-type carbon-containing modulation layer 7 is not less than 1×10¹⁷ atoms/cm³. The p-type carbon-containing modulation layer 7 may be doped with a p-type dopant in an amount of not less than 1×10¹⁹ atoms/cm³. In this embodiment, the p-type dopant is present in an amount not less than 5×10¹⁹ atoms/cm³, such as ranging from 1×10²⁰ atoms/cm³ to 2×10²⁰ atoms/cm³. By increasing amount of the p-type dopant, the p-type hole injection efficiency may be improved.

The p-type carbon-containing modulation layer 7 may have a thickness ranging from 3 nm to 70 nm, such as 20 nm to 50 nm. In certain embodiments, the p-type carbon-containing modulation layer 7 has a thickness of 10 nm.

The p-type carbon-containing modulation layer 7 may be made of a material represented by a chemical formula of AlₐIn_{b}Ga_{1-a-b}N, wherein a≥0, b≥0 and a+b≤1. The p-type carbon-containing modulation layer 7 may be formed as a single-layer structure, or a multi-layered structure (such as a superlattice structure, e.g., AlInGaN/GaN). In certain embodiments, in the p-type carbon-containing modulation layer 7, the amount of the p-type dopant is greater than the amount of carbon.

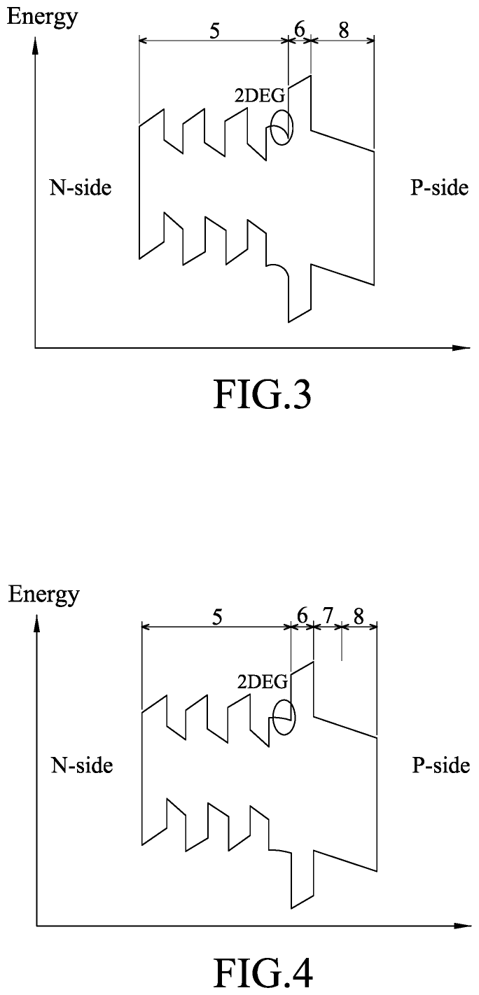

The p-type carbon-containing modulation layer 7 is configured to reduce a two-dimensional electron gas (2DEG) due to band bending between the light emitting element 5 and the p-type nitride-based semiconductor layer 9. FIGS. 3 and 4 respectively show schematic energy diagram of a conventional LED (without formation of the p-type carbon-containing modulation layer 7 between the light emitting element 5 and the p-type nitride-based semiconductor layer 9) and that of the embodiment of the nitride-based LED according to the disclosure. It can be seen that, at an interface between the light emitting element 5 and the p-type nitride-based semiconductor layer 9, the nitride-based LED according to the disclosure shows a smaller band bending (see the circled portion in FIG. 4) compared with the band bending of the conventional LED (see the circled portion in FIG. 3). By including the p-type carbon-containing modulation layer 7, the higher amount of carbon in the p-type carbon-containing modulation layer 7 may move Fermi level of the p-type nitride-based semiconductor layer 9 up, so as to reduce band bending at an interface between the light emitting element 5 and the p-type nitride-based semiconductor layer 9. Therefore, generation of 2DEG may be greatly avoided, and ineffective recombination of electrons and holes at the 2DEG can be reduced, so as to improve light emitting efficiency of the nitride-based LED of this disclosure.

To further avoid electron overflow, the epitaxial structure may further include a second electron blocking layer 8 that is disposed between the p-type carbon-containing modulation layer 7 and the p-type nitride-based semiconductor layer 9. The second electron blocking layer 8 may be made of a material represented by a chemical formula of AlₑIn_{f}Ga_{1-e-f}N, wherein e>0, f≥0 and e+f≤1. The second electron blocking layer 8 may be formed as a single-layer structure, or a multi-layered structure (such as a superlattice structure, e.g., AlInGaN/GaN). In certain embodiments, an amount of carbon present in the second electron blocking layer 8 is higher than that present in the p-type carbon-containing modulation layer 7. In other embodiments, the amount of carbon present in the second electron blocking layer 8 is lower than that present in the p-type carbon-containing modulation layer 7. The amount of carbon present in the second electron blocking layer 8 may be altered by adjusting the growth temperature, ratio of group V semiconductor material to group III semiconductor material, growth pressure or composition of a carrier gas used during epitaxial growth of the second electron blocking layer 8. The second electron blocking layer 8 may have a thickness ranging from 10 nm to 80 nm, such as not less than 12 nm.

The epitaxial structure may further include a buffer layer 2 that is disposed between the substrate and the n-type nitride-based semiconductor layer 3. The buffer layer 2 may have a lattice constant between a lattice constant of the substrate 1 and a lattice constant of the n-type nitride-based semiconductor layer 3, so as to reduce lattice mismatch of the substrate 1 and the n-type nitride-based semiconductor layer 3. The buffer layer 2 may be made of a material represented by a chemical formula of AlₓIn_{y}Ga_{1-x-y}N, wherein 0≤x≤1 and 0≤y≤1. For instance, the buffer layer 2 may be made of AlN, GaN, AlGaN, AlInGaN, or InGaN.

In certain embodiments, the buffer layer 2 includes a low temperature GaN nucleation sublayer that has a thickness ranging from 25 nm to 40 nm, a high temperature GaN buffer sublayer that has a thickness ranging from 0.2 μm to 1 μm, and a two-dimensional GaN sublayer that has a thickness ranging from 1 μm to 2 μm.

The epitaxial structure may further include a stress release layer 4 that is disposed between the n-type nitride-based semiconductor layer 3 and the light emitting layer 5. The stress release layer 4 may release stress generated during growth of the n-type nitride-based semiconductor layer 3, and may be used for adjusting the size of V-pits formed in the epitaxial structure so as to enhance brightness of light emitted by the nitride-based LED. The stress release layer 4 may be formed as a single-layer structure. Alternatively, the stress release layer 4 is formed as a multi-layered structure, such as a superlattice structure, e.g., including alternately stacked InGaN and GaN.

According to this disclosure, a method for making the abovementioned embodiment of the nitride-based LED according to the disclosure includes the following steps.

The substrate 1 is first provided. In this embodiment, the substrate is a sapphire substrate.

The epitaxial structure is then formed on the substrate 1. That is, the epitaxial layer includes the buffer layer 2, the n-type nitride-based semiconductor layer 3, the stress release layer 4, the light emitting element 5, the first electron blocking layer 6, the p-type carbon-containing modulation layer 7, the second electron blocking layer 8 and the p-type nitride-based semiconductor layer 9 that are sequentially formed on the substrate 1 in such order.

The buffer layer 2 may be formed by a physical vapor deposition (PVD) process. Each of the n-type nitride-based semiconductor layer 3, the stress release layer 4, the light emitting element 5, the first electron blocking layer 6, the p-type carbon-containing modulation layer 7, the second electron blocking layer 8 and the p-type nitride-based semiconductor layer 9 may be formed by a metal-organic chemical vapor deposition (MOCVD) process.

In sum, by including the p-type carbon-containing modulation layer 7 that has an amount of carbon higher than the amount of carbon present in each of the light emitting element 5 and the first electron blocking layer 6, Fermi level of the p-type nitride-based semiconductor layer 9 is increased and band bending at an interface between the light emitting element 5 and the p-type nitride-based semiconductor layer 9 is reduced. Therefore, generation of 2DEG can be avoided, and possibility of ineffective recombination of electrons and holes at the 2DEG can be reduced, so that the light emitting efficiency of the nitride-based LED of this disclosure can be greatly improved.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is considered the exemplary embodiments, it is understood that this disclosure is not limited to the disclosed embodiment but is intended to cover various arrangements included within the spirit and scope of the broadest interpretation so as to encompass all such modifications and equivalent arrangements.

What is claimed is:

1. A nitride-based light emitting diode (LED), comprising:
a substrate; and
an epitaxial structure which includes an n-type nitride-based semiconductor layer, a light emitting element, a first electron blocking layer, a p-type carbon-containing modulation layer and a p-type nitride-based semiconductor layer that are sequentially disposed on said substrate in such order;
wherein an amount of carbon present in said p-type carbon-containing modulation layer is higher than an amount of carbon present in each of said light emitting element and said first electron blocking layer.

2. The nitride-based LED of claim 1, wherein the amount of carbon present in said first electron blocking layer is higher than that present in said light emitting element.

3. The nitride-based LED of claim 1, wherein the amount of carbon present in said p-type carbon-containing modulation layer ranges from 5×10¹⁶ atoms/cm³ to 1×10¹⁸ atoms/cm³.

4. The nitride-based LED of claim 1, wherein said p-type carbon-containing modulation layer is doped with a p-type dopant in an amount of not less than 1×10¹⁹ atoms/cm³.

5. The nitride-based LED of claim 1, wherein said p-type carbon-containing modulation layer has a thickness ranging from 3 nm to 70 nm.

6. The nitride-based LED of claim 1, wherein said p-type carbon-containing modulation layer is made of a material represented by a chemical formula of AlₐIn_{b}Ga_{1-a-b}N, wherein a≥0, b≥0 and a+b≤1.

7. The nitride-based LED of claim 1, wherein said p-type carbon-containing modulation layer is formed as one of a single-layer structure and a superlattice structure.

8. The nitride-based LED of claim 4, wherein, in said p-type carbon-containing modulation layer, the amount of said p-type dopant is greater than the amount of carbon.

9. The nitride-based LED of claim 1, wherein said light emitting element includes at least one well layer and at least one barrier layer, said first electron blocking layer having a band gap greater than that of said barrier layer of said light emitting element.

10. The nitride-based LED of claim 9, wherein the band gap of said first electron blocking layer is greater than that of gallium nitride.

11. The nitride-based LED of claim 9, wherein an amount of aluminum present in said first electron blocking layer is greater than that present in said barrier layer of said light emitting element.

12. The nitride-based LED of claim 1, wherein said first electron blocking layer is made of a material represented by a chemical formula of Al_{c}In_{d}Ga_{1-c-d}N, wherein c>0, d≥0 and c+d≤1.

13. The nitride-based LED of claim 1, wherein said first electron blocking layer has a thickness ranging from 1 nm to 50 nm.

14. The nitride-based LED of claim 1, wherein said epitaxial structure further includes a second electron blocking layer that is disposed between said p-type carbon-containing modulation layer and said p-type nitride-based semiconductor layer, and that is made of a material represented by a chemical formula of AlₑIn_{f}Ga_{1-e-f}N, wherein e>0, f≥0 and e+f≤1.

15. The nitride-based LED of claim 14, wherein said second electron blocking layer has a thickness ranging from 10 nm to 80 nm.
